(19) United States
(12) Patent Application Publication
(10) Pub. No.: US 2016/0313478 A1
(43) Pub. Date: Oct. 27, 2016

(54) FLEXIBLE SUBSTRATE AND DISPLAY DEVICE INCLUDING THE SAME

(71) Applicant: Samsung Display Co., Ltd., Yongin-si (KR)

(72) Inventors: Dae Ho LEE, Seoul (KR); Hee-Keun LEE, Suwon-si (KR)

(21) Appl. No.: 14/931,446

(22) Filed: Nov. 3, 2015

(30) Foreign Application Priority Data
Apr. 27, 2015 (KR) 10-2015-0059154

(51) Int. Cl. G02B 5/02; G02F 1/1333; G02F 1/1335; H01L 51/00

(52) U.S. Cl. CPC G02B 5/0242; H01L 51/0097; G02F 1/133305; G02F 1/133377; G02F 1/133504; H01L 2251/5338

(57) ABSTRACT

Provided is a flexible substrate for a display device including: a plastic layer; and particles positioned in the plastic layer and reducing a thickness factor influencing warpage of the plastic layer. Further, provided is a display device including: a flexible substrate; a thin film transistor positioned on the flexible substrate; a pixel electrode positioned on the thin film transistor; and an electro-optical active layer positioned on the pixel electrode.

### CROSS-REFERENCE TO RELATED APPLICATION

This application claims priority to and the benefit of Korean Patent Application No. 10-2015-0059154 filed in the Korean Intellectual Property Office on Apr. 27, 2015, the entire contents of which are incorporated herein by reference.

### BACKGROUND

(a) Technical Field The present disclosure relates to a flexible substrate and a display device including the same.

(b) Description of the Related Art

A flexible display device is foldable or bendable like paper, has an outer design that is free, and has a flexible substrate. As a result, the flexible display device is a display device that is not easily broken yet is easily portable. According to a technical level, a rugged display device that is durable to impact, a bendable or foldable display device that is bendable or foldable and of which a predetermined partial design is free, a rollable display device that is freely rollable like a roll form, and the like may be divided.

In order to implement the flexible display device, a flexible substrate, organic/inorganic materials for a low process, a flexible electronic device, passivation layer and blocking layer techniques, a packaging technique, and the like are complexly required. Among the constituent elements, the flexible substrate has been recognized as an important component that determines performance, reliability, prices, and the like of the flexible display device.

As the flexible substrate, a metal foil substrate, a thin glass substrate, a plastic substrate, and the like have been studied. The plastic substrate has received attention as a suitable material due to ease of processing, its low weight, suitability of a continuous process, and the like. The display device is manufactured by forming various elements on the plastic substrate while the plastic substrate is formed or attached onto a carrier substrate. However, due to a difference in coefficient of thermal expansion CTE between the carrier substrate and the plastic substrate, warpage of the plastic substrate occurs, and as a result, defects, such as a crack or wrinkling, may be generated in the plastic substrate and the elements formed thereon.

The above information disclosed in this Background section is only for enhancement of understanding of the background of the disclosure and therefore may contain information that does not form the prior art that is already known in this country to a person of ordinary skill in the art.

### SUMMARY

The present disclosure provides a flexible substrate, and a display device including the same, having advantages of suppressing warpage of a plastic substrate from being generated.

An exemplary embodiment of the present disclosure provides a flexible substrate for a display device including: a plastic layer; and particles positioned in the plastic layer and reducing a thickness factor influencing warpage of the plastic layer.

Each particle may have a thickness of about 1 to about 10 μm.

The particles may be made of the same material as the plastic layer.

The particles may be coated with a shell coating.

The shell coating may be made of an inorganic material.

The particle may include a light-diffusing material.

The plastic layer may include a plurality of layers, and the particles may be positioned only in a subset of layers of the plurality of layers.

A pattern may be formed on an interface between the plurality of layers.

Another exemplary embodiment of the present disclosure provides a display device including: a flexible substrate; a thin film transistor positioned on the flexible substrate; a pixel electrode positioned on the thin film transistor; and an electro-optical active layer positioned on the pixel electrode. The flexible substrate includes a plastic layer; and particles positioned in the plastic layer and reducing a thickness factor influencing warpage of the plastic layer.

Each particle may have a thickness of about 1 to about 10 μm.

The particles may be made of the same material as the plastic layer.

The particles may be coated with a shell coating a surface of the core.

The shell coating may be made of an inorganic material.

The particle may include a light-diffusing material.

The plastic layer may include a plurality of layers, and the particles may be positioned only in a subset of layers of the plurality of layers.

A pattern may be formed on an interface between the plurality of layers.

The electro-optical active layer may be a liquid crystal layer positioned in the microcavity on the pixel electrode.

The display device may further include a common electrode positioned on the liquid crystal layer and a roof layer positioned on the common electrode.

The electro-optical active layer may be an organic emission layer.

According to an exemplary embodiment of the present disclosure, the particles distributed in the plastic substrate reduce the thickness factor, which influences the warpage of the plastic substrate, to suppress or minimize the warpage of the plastic substrate from being generated when the display device is manufactured. As a result, since cracks and the like may be prevented from being generated on the plastic substrate or the element formed thereon, damage to the display device or an image-quality defect may be prevented. In addition, other advantages are described or recognized throughout the specification.

### BRIEF DESCRIPTION OF THE DRAWINGS

FIG. 1 is a cross-sectional view of a flexible substrate according to an exemplary embodiment of the present disclosure.

FIG. 2 is a graph illustrating warpage simulation data according to a thickness of the plastic substrate.

FIGS. 3 and 4 illustrate a graph and a distribution diagram illustrating a thickness according to a position of the plastic substrate according to an exemplary embodiment of the present disclosure, respectively.

FIGS. 5, 6 and 7 are cross-sectional views of plastic substrates according to some exemplary embodiments of the present disclosure.

FIG. 8 is a plan view illustrating four pixel areas adjacent to each other in a liquid crystal display according to an exemplary embodiment of the present disclosure.

FIG. 9 is a cross-sectional view taken along line A-A of FIG. 8.

FIG. 10 is a cross-sectional view taken along line B-B of FIG. 9.

FIGS. 11, 12, 13, 14, 15, 16, 17, 18 and 19 are process cross-sectional views illustrating a process of manufacturing a display device according to an exemplary embodiment of the present disclosure.

### DETAILED DESCRIPTION OF THE EMBODIMENTS

The present system and method are described more fully hereinafter with reference to the accompanying drawings in which exemplary embodiments of the present system and method are shown. As those skilled in the art would realize, the described embodiments may be modified in various different ways, all without departing from the spirit or scope of the present system and method.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element, or intervening elements may also be present. In contrast, when an element is referred to as being “directly on” another element, there are no intervening elements present.

A flexible substrate, a display device including the same, and a manufacturing method thereof according to an exemplary embodiment of the present disclosure is described in detail with reference to the accompanying drawings.

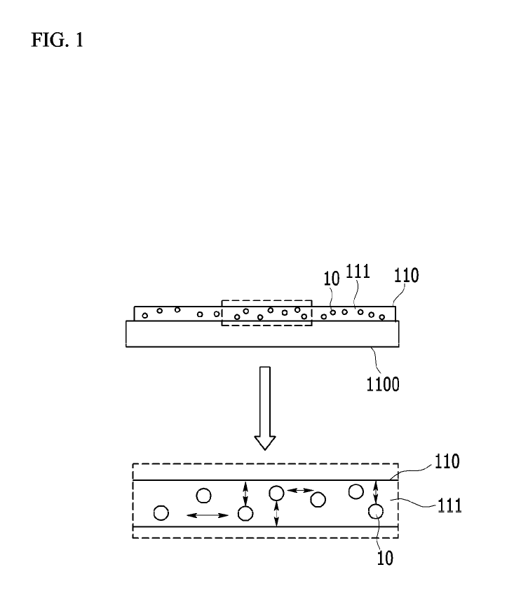

FIG. 1 is a cross-sectional view of a flexible substrate according to an exemplary embodiment of the present disclosure.

In FIG. 1, an upper view illustrates a state in which a flexible substrate 110 is positioned on a carrier substrate 1100, and a lower view illustrates an enlarged part of the flexible substrate 110. Various elements, such as a thin film transistor and a wire, an insulating layer, and the like configuring the display device, are formed on the flexible substrate 110. When those elements are formed on the flexible substrate 110, the carrier substrate 1100 is used. That is, the carrier substrate 1100 is a plate is not a constituent element of the display device but an intermediate element used in a process of manufacturing the display device, for example, a flat glass substrate.

In a process, rigidity of the substrate acts as an important parameter. For example, when a warpage phenomenon of the substrate occurs during the process, vacuum equipment is not smoothly used, and when force is applied to planarize the substrate, a crack in the layer is caused due to thin film stress. Accordingly, after the process is performed by forming or attaching the flexible substrate 110 on the carrier substrate 1100, such as glass, the carrier substrate 1100 is separated from the flexible substrate 110 after the predetermined process. However, during the process, since the carrier substrate 1100 and the flexible substrate 110 are attached to each other, the carrier substrate 1100 and the flexible substrate 110 are bent due to a difference in coefficient of thermal expansion between the substrates. The degree of warpage is determined according to a thickness of the substrate, a process temperature applied to the substrate, a difference in coefficient of thermal expansion, and the like, which are called warpage effect factors. For example, a substrate with a relatively high coefficient of thermal expansion is further extended during exposure to a high temperature, and the warpage of the substrate occurs while retraction is applied during exposure to room temperature again. As a result, cracks and the like may be generated on the flexible substrate 110 or the element and the layer formed thereon.

The flexible substrate 110 includes a plastic layer 111 made of plastic that is a transparent insulating material and particles 10 in the plastic layer 111.

The plastic layer 111 may be made of plastic with relatively high heat resistance, such as polyamide (PA), polyimide (PI), and polyarylate (PAR). For example, the plastic layer 111 may be made of a thermoplastic semicrystalline polymer, such as polyethylene terephthalate (PET), polyethylene naphthalate (PEN), and polyethylene ether ketone (PEEK), and a thermoplastic amorphous polymer, such as polycarbonate (PC) and polyethylene sulfonate (PES).

The particles 10 are dispersed in the plastic layer 111 and may be randomly distributed. The particle 10 becomes a release point of stress exerting inside the plastic layer 111 and may reduce a thickness factor, which influences the warpage of the plastic layer 111. The thickness factor is described below.

The particle 10 may be, for example, a spherical or oval bead or a long and narrow rod, or may have various shapes. The particle 10 has a thickness (a diameter in the case of a bead) smaller than the thickness of the plastic layer 111 so as to minimize a negative effect of the particle 10 on the planarization of the flexible substrate 110. The particle 10 may have a thickness of a micrometer unit, for example, a thickness of several micrometers (for example, about 1 to about 10 micrometers), and may have a thickness of tens of micrometers when the plastic layer 111 is thick. The particles 10 may have the same size and may also have two or more various sizes.

The particle 10 may be made of a transparent material having a refractive index that is equal or similar to that of the plastic layer 111 so as to minimize an effect on an optical characteristic, such as transmittance or a refractive index, of the flexible substrate 110. Since the refractive indexes are equal to each other when the materials are the same as each other, the particle 10 may be formed of the same plastic as the plastic of the plastic layer 111. However, in this case, since the particle 10 may be dissolved when the plastic for forming the flexible substrate 110 is dissolved, the particle 10 may have a core-shell structure in which a shell is formed on a surface of the core. The core material may be, for example, plastic and may be made of the same material as the plastic layer 111. The shell may be formed by coating a transparent inorganic material, such as silicon oxide (SiOx) and silicon nitride (SiNx), as the core material. The shell may be a single layer or a multilayer. However, the particle 10 having the core-shell structure may influence the refractive index of the flexible substrate 110 due to the difference in refractive index between the core material and the shell (coating layer) material, and silicon oxide is more advantageous as the shell material in terms of the refractive index. The particle 10 may also be made of one material that does not dissolved in a solvent of the plastic material.

The effect on the optical characteristic of the flexible substrate 110 due to the particles 10 may be importantly considered in a display device in which light passes through the flexible substrate 110, for example, a display device (particularly, a liquid crystal display) using a backlight, a bottom emission type display device (particularly, an organic light emitting diode display), a transparent display device, or the like. However, for example, in the case of a top emission type display device, although the particle 10 is not transparent, or a difference from the plastic layer 111 in the refractive index is large, it does not matter.

The particle 10 is formed of a material having a specific function to grant the specific function to the flexible substrate 110. For example, the particle 10 may be formed of a material or a structure for diffusing light. That is, it may be advantageous for the particle 10 having the aforementioned core-shell structure to diffuse the light by using the difference in refractive index between the core material and the shell material. In this case, the particles 10 may be used to reduce the thickness factor of the flexible substrate 110 and diffuse the light from the backlight so that the backlight light may be further evenly distributed, or some constituent elements (for example, a diffuser) of the backlight unit may be replaced. As another example, the particle 10 may be made of a material having a polarization function and may also be made of a material having two or more complex functions.

The flexible substrate 110 may be formed by a solvent caster method or a stretching method according to a characteristic of the plastic. The solvent caster method may be a method of mixing and dissolving plastic and an additive to a solvent and mixing the particles 10 to ensure mobility and then forming the substrate by volatilizing the solvent while passing through a slit die with a fixed thickness. In this case, the flexible substrate 110 may be formed by applying or coating and curing a plastic solution mixed with the particles 10 on the carrier substrate 1100. The stretching method may be a method of forming the substrate by melting and stretching the plastic mixed with the particles 10 in two directions.

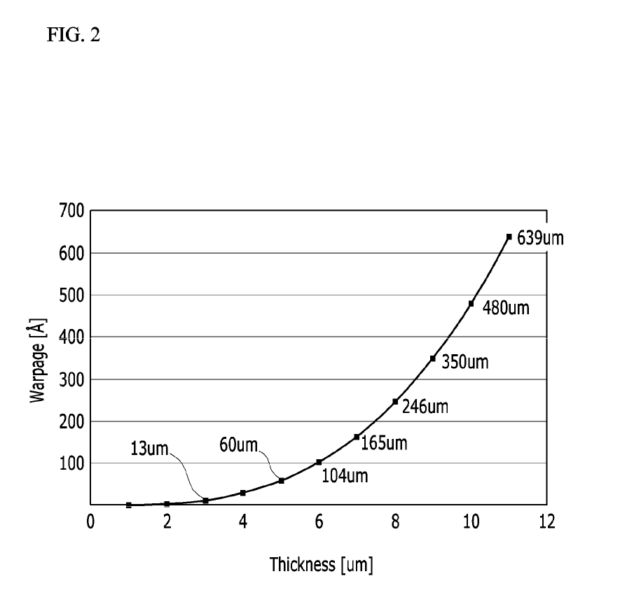

Hereinafter, a principle of suppressing the warpage of the substrate from being generated due to the particles 10 included in the flexible substrate 110 is described with reference to FIG. 2.

FIG. 2 is a graph illustrating warpage simulation data according to a thickness of the plastic substrate.

The warpage of the flexible substrate made of plastic is proportional to Equation of bh³/12. Here, b represents the inertia moment of the substrate, and h represents a thickness of the substrate. Accordingly, as the thickness of the plastic substrate is increased, the degree of the warpage is more largely shown. The particles included in the flexible substrate reduce the thickness factor, which influences the warpage of the flexible substrate, according to sizes of the particles. For example, when a thickness of a polyimide flexible substrate without particles is 10 μm, the warpage is about 480 μm. However, when a flexible substrate with the same thickness includes particles of 3 μm, the warpage may be decreased to about 165 μm. When a flexible substrate with the same thickness includes particles of 5 μm, the warpage may be decreased to about 60 μm. When a flexible substrate with the same thickness includes particles of 7 μm, the warpage may be decreased to about 13 μm. Accordingly, the warpage of the substrate may be reduced according to sizes of the particles or the density of the particles in the flexible substrate.

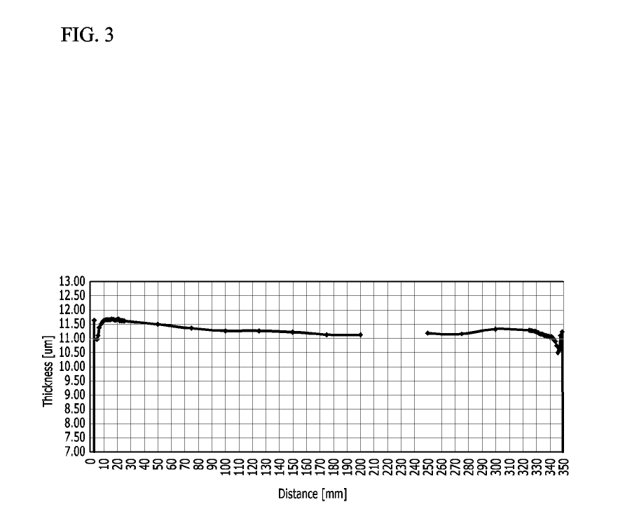

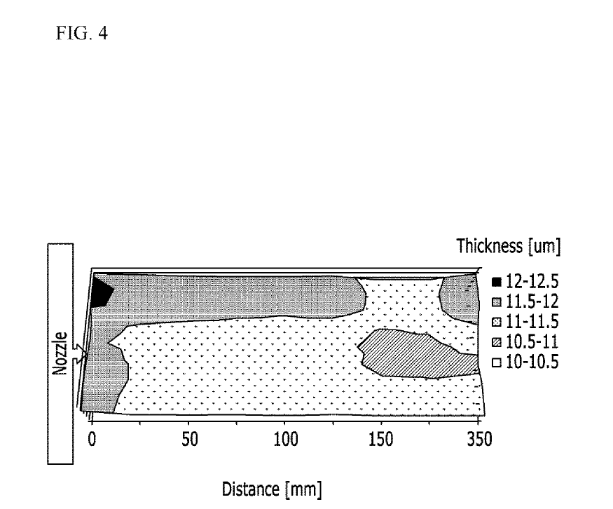

The particles included in the plastic layer may influence uniformity of the flexible substrate, and when the influence is large, the flexible substrate may not be suitable as the substrate of the display device. This is described with reference to FIGS. 3 and 4.

FIGS. 3 and 4 illustrate a graph and a distribution diagram illustrating a thickness according to a position of the plastic substrate according to an exemplary embodiment of the present disclosure, respectively.

In an experiment, after the plastic substrate is formed by mixing and coating a bead with a size of several micrometers (maximum about 10 micrometers) to polyimide, a thickness for each position of the substrate is measured. As a result, coating uniformity is shown as 6.06% in a region where a distance from an edge, which is a start portion of the coating layer, is 10 mm and 5.35% in a region where a distance from the edge is 15 mm. Accordingly, when the plastic substrate is formed by mixing particles with sizes smaller than the thickness of the plastic substrate, it can be seen that the coating uniformity is within 10% which may be considered to be suitable as the substrate of the display device.

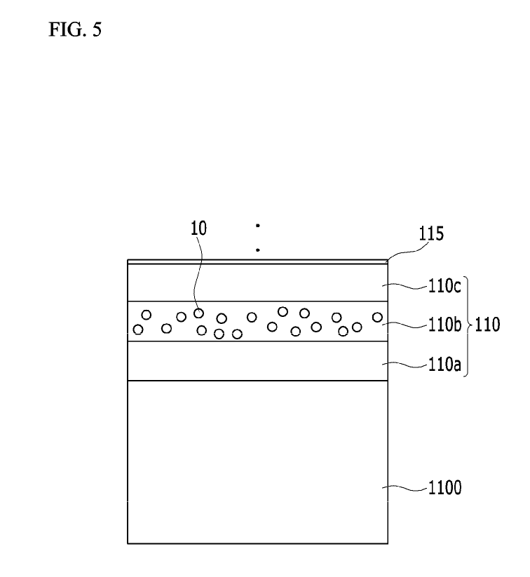

Hereinabove, the example where the flexible substrate is formed as the single layer was described. However, the flexible substrate may be formed as a multilayer, be formed so that particles are distributed only on some layers, and also be formed to have various surface patterns. Such examples are described with reference to FIGS. 5 to 7.

FIGS. 5 to 7 are cross-sectional views of plastic substrates according to some exemplary embodiments of the present disclosure.

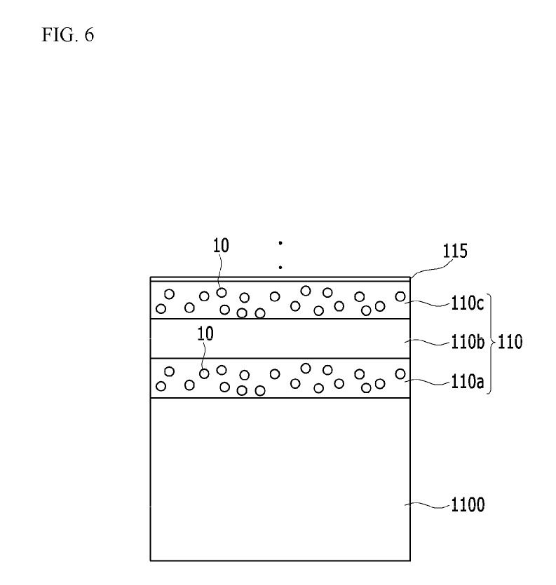

Referring to FIGS. 5 and 6, the flexible substrate 110 includes a plurality of layers 110a, 110b, and 110c. In the case of an example of FIG. 5, particles 10 are included only in the intermediate layer 110b, and in the case of an example of FIG. 6, the particles 10 are not included in the intermediate layer 110b but are included in the upper layer 110c and the lower layer 110a. As such, the flexible substrate 110 may be configured by alternately laminating a layer with the particles 10 and a layer without the particles 10. Although the flexible substrate 110 including three layers is illustrated, it is just an example and may include two or four or more layers. A barrier layer 115 may be formed on the flexible substrate 110, and may also be selectively formed even between the plurality of layers 110a, 110b, and 110c. The barrier layer 115 is described below.

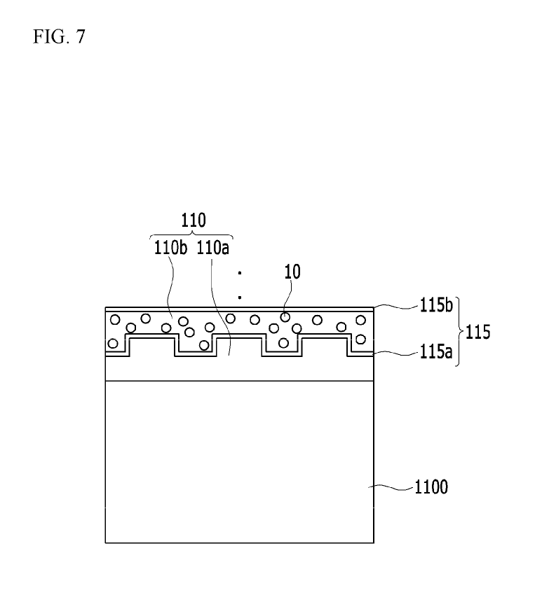

Referring to FIG. 7, the flexible substrate 110 includes the plurality of layers 110a and 110b, and like the examples of FIGS. 5 and 6, the layer 110a without the particles and the layer 110b with the particles are alternately laminated. FIG. 7 differs, however, in that an interface between the layers 110a and 110b may be formed with various patterns such as an uneven pattern. The barrier layer 115 may be formed between the plurality of layers 110a and 110b and also be formed on the flexible substrate 110.

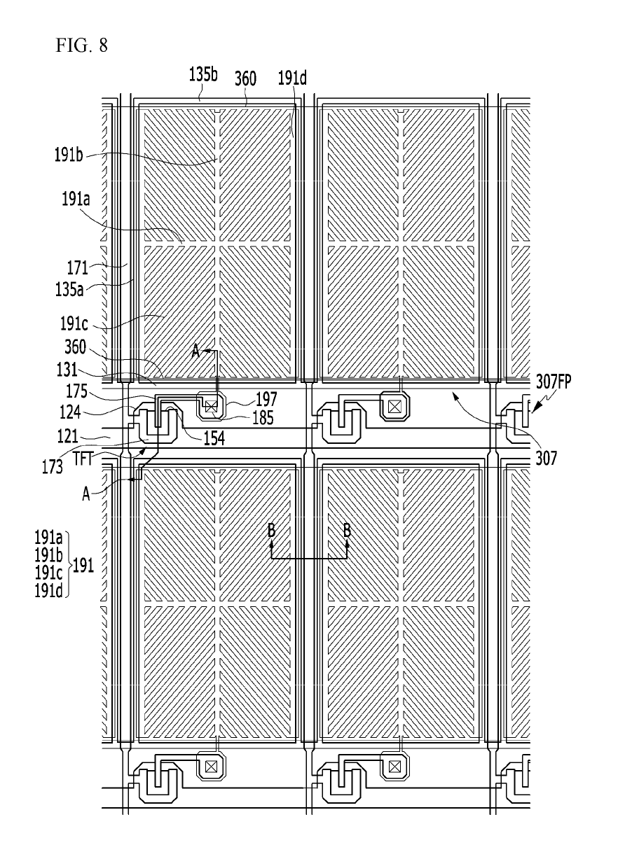

Hereinafter, as the display device including the flexible substrate described above, a liquid crystal display in which a liquid crystal layer is formed as an electro-optical active layer in a microcavity is exemplified with reference to FIGS. 8 to 10. However, the present disclosure is not limited to the liquid crystal display, and may be applied to other display devices, such as an organic light emitting diode display in which an organic emission layer is formed on the flexible substrate as the electro-optical active layer.

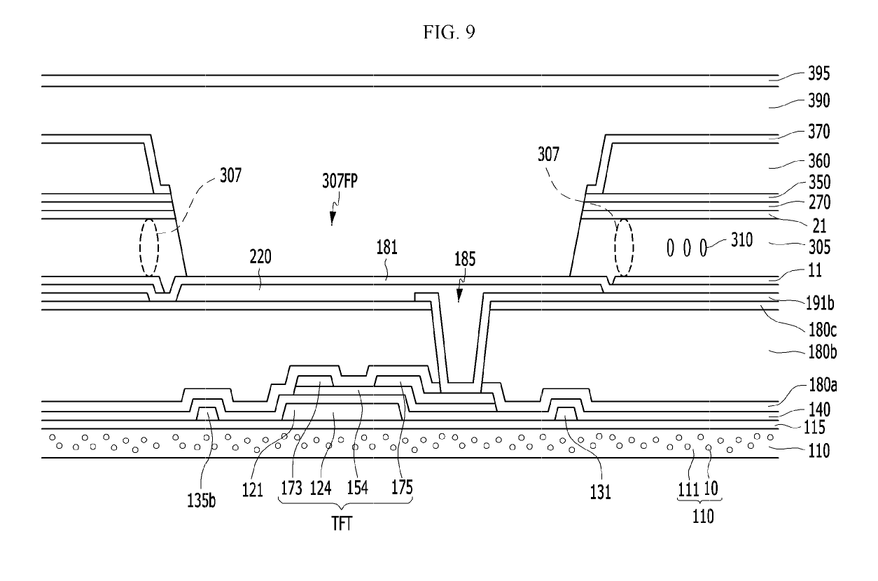

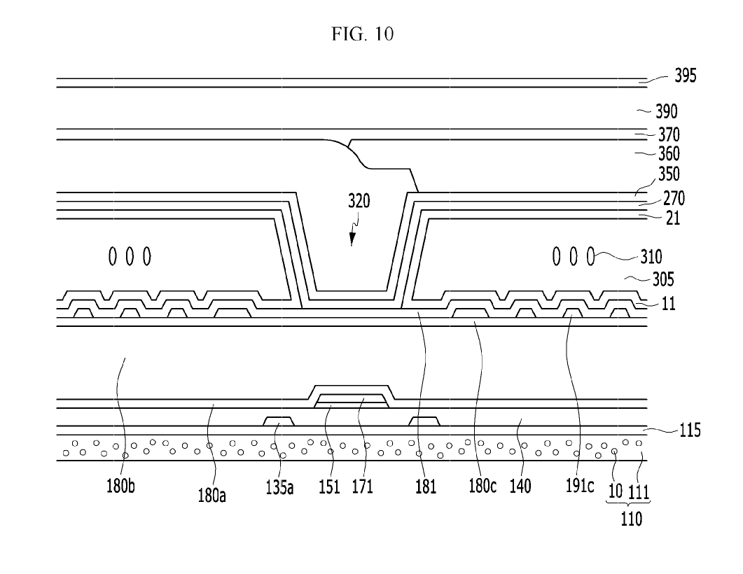

FIG. 8 is a plan view illustrating four pixel areas adjacent to each other in a liquid crystal display according to an exemplary embodiment of the present disclosure. FIG. 9 is a cross-sectional view taken along line A-A of FIG. 8. FIG. 10 is a cross-sectional view taken along line B-B of FIG. 9.

FIG. 8 illustrates 2×2 pixel areas, which are some areas among a plurality of pixel areas, and in the liquid crystal display, the pixel areas may be repeatedly arranged at up, down, left, and right sides.

Referring to FIGS. 8 to 10, the barrier layer 115 is formed on the flexible substrate 110 made of plastic or the like. As described above, in the flexible substrate 110, the particles 10 are distributed in the plastic layer 111, and may serve to suppress the warpage from being generated by reducing the thickness factor of the plastic layer 111.

Unlike a glass substrate, in the plastic substrate, since moisture, oxygen, or the like, which may cause deterioration of an image characteristic of the display device, is easily permeated, the barrier layer 115 for preventing the moisture, oxygen, and the like from being permeated may be formed. The barrier layer 115 may be formed of a single layer or a multilayer and made of an inorganic material or organic/inorganic materials. For example, the barrier layer 115 may be formed by depositing an inorganic material, such as silicon oxide and silicon nitride, by a method such as a plasma enhanced chemical vapor deposition (PECVD) method, an atmospheric pressure CVD (APCVD) method, and a low pressure CVD (LPCVD) method. To protect the barrier layer 115, an upper overcoat layer (not illustrated), such as a transparent polymer layer, may be formed on the barrier layer 115. When the flexible substrate 110 is formed as the multilayer, the barrier layer (not illustrated) may also be formed between the layers.

A gate line 121 and a storage electrode line 131 are formed on the barrier layer 115. The gate line 121 includes a gate electrode 124. The storage electrode line 131 extends mainly in a horizontal direction and is configured to transfer a predetermined voltage such as a common voltage. The storage electrode line 131 may include a pair of vertical portions 135a that extends substantially vertically to the gate line 121 and a horizontal portion 135b connecting ends of the pair of vertical portions 135a to each other. The vertical portions 135a and the horizontal portion 135b may have a structure surrounding a pixel electrode 191.

A gate insulating layer 140 is formed on the gate line 121 and the storage electrode line 131. On the gate insulating layer 140, a semiconductor layer 151, which is positioned below a data line 171, and a semiconductor layer 154, which is positioned below source/drain electrodes and at a channel portion of a thin film transistor TFT, are formed. An ohmic contact (not illustrated) may be formed among the semiconductor layers 151 and 154, the data line 171, and the source/drain electrodes.

Data conductors 171, 173, and 175 including a source electrode 173, a data line 171 connected to the source electrode 173, and a drain electrode 175 are formed on the semiconductor layers 151 and 154 and the gate insulating layer 140.

The gate electrode 124, the source electrode 173, and the drain electrode 175 form the thin film transistor TFT together with the semiconductor layer 154, and a channel of the thin film transistor TFT is formed in a portion between the source electrode 173 and the drain electrode 175 of the semiconductor layer 154.

A first passivation layer 180a is formed on an exposed portion of the semiconductor layer 154 that is not covered by the data conductors 171, 173, and 175. The first passivation layer 180a may include an inorganic material such as silicon nitride and silicon oxide.

A second passivation layer 180b and a third passivation layer 180c may be positioned on the first passivation layer 180a. The second passivation layer 180b may be made of an organic material, and the third passivation layer 180c may include an inorganic material such as silicon nitride and silicon oxide. One or two of the first passivation layer 180a, the second passivation layer 180b, and the third passivation layer 180c may be omitted.

A contact hole 185 is formed by passing through the first passivation layer 180a, the second passivation layer 180b, and the third passivation layer 180c, and the pixel electrode 191 positioned on the third passivation layer 180c may be electrically and physically connected with the drain electrode 175 through the contact hole 185. Hereinafter, one example of the pixel electrode 191 is described in detail.

The pixel electrode 191 may be made of a transparent conductive material such as indium tin oxide (ITO) and indium zinc oxide (IZO). The pixel electrode 191 has an overall shape of a quadrangle and includes a cross stem configured by a horizontal stem 191a and a vertical stem 191b crossing the horizontal stem 191a. Further, the pixel electrode 191 is divided into four domains by the horizontal stem 191a and the vertical stem 191b, and each domain includes a plurality of minute branches 191c. Further, the pixel electrode 191 may further include an outer stem 191d connecting the minute branches 191c at the left and right outer edges, and the outer stem 191d may be positioned to be extended to the upper portion or the lower portion of the pixel electrode 191.

The minute branches 191c of the pixel electrode 191 form an angle of approximately 40° to 45° with the gate line 121 or the horizontal stem 191a. Further, the minute branches of two adjacent domains may be perpendicular to each other. Further, widths of the minute branches are gradually increased, or distances between the minute branches 191c may be different from each other.

The pixel electrode 191 includes an extension 197, which is connected to a lower end of the vertical stem 191b and has a larger area than the vertical stem 191b, and is physically and electrically connected with the drain electrode 175 through the contact hole 185 at the extension 197 to receive a data voltage from the data electrode 175.

The description of the thin film transistor TFT and the pixel electrode 191 described above is just an example, and a structure of the thin film transistor and a design of the pixel electrode may be variously modified to improve side visibility.

A light blocking member 220 is positioned on the pixel electrode 191 to cover a region with the thin film transistor TFT. The light blocking member 220 may be formed in an extending direction of the gate line 121. The light blocking member 220 may be formed of a material that blocks light.

An insulating layer 181 may be formed on and cover the light blocking member 220 and formed to be extended to the upper side of the pixel electrode 191. The insulating layer 181 may be made of silicon nitride or silicon oxide.

A lower alignment layer 11 is formed on the pixel electrode 191, and may be a vertical alignment layer. The lower alignment layer 11 may be formed by including at least one of materials that are generally used in a liquid crystal alignment layer, such as polyamic acid, polysiloxane, polyimide, or the like. The lower alignment layer 11 may be a photo-alignment layer.

An upper alignment layer 21 is positioned at a portion facing the lower alignment layer 11, and a plurality of microcavities 305 is formed between the lower alignment layer 11 and the upper alignment layer 21. A liquid crystal material including liquid crystal molecules 310 is injected into the microcavities 305 to form a liquid crystal layer. The microcavities 305 may be formed in a column direction, that is, a vertical direction of the pixel electrode 191. In the exemplary embodiment, the alignment material forming the alignment layers 11 and 21 and the liquid crystal material including the liquid crystal molecules 310 may be injected into each microcavity 305 by using capillary force through an inlet 307 that exposes the microcavity 305. The lower alignment layer 11 and the upper alignment layer 21 are divided according to a position and may be connected to each other, and may be simultaneously formed.

The microcavities 305 are divided by a plurality of trenches 307FP positioned at a portion overlapping with the gate line 121 in a vertical direction and may be formed in a column direction, that is, a vertical direction of the pixel electrode 191. Further, microcavities 305 are divided by partition wall portions 320 in a horizontal direction and may be formed in a row direction of the pixel electrode 191, that is, a horizontal direction in which the gate line 121 extends. Each of the plurality of microcavities 305 may correspond to one pixel area or two or more pixel areas, and the pixel area may correspond to an area for displaying an image.

A common electrode 270 and a lower insulating layer 350 are positioned on the upper alignment layer 21. When the common electrode 270 receives a common voltage, it generates an electric field together with the pixel electrode 191 to which the data voltage is applied to determine tilt directions of the liquid crystal molecules 310 positioned in the microcavity 305 between the two electrodes. Accordingly, the pixel electrode 191 and the common electrode 270 are referred to as field generating electrodes. The common electrode 270 forms a capacitor together with the pixel electrode 191 such that the applied voltage is maintained for a period of time even after the thin film transistor is turned off. The lower insulating layer 350 may be made of silicon nitride or silicon oxide.

Although the example in which the common electrode 270 is formed on the microcavity 305 is illustrated, in another exemplary embodiment, the common electrode 270 may be formed below the microcavity 305, and thus the liquid crystal may be driven in an in-plane switching mode.

A roof layer 360 is positioned on the lower insulating layer 350. The roof layer 360 serves to support the microcavity 305, which is a space between the pixel electrode 191 and the common electrode 270 to be formed.

The roof layer 360 may include a photoresist or other organic materials. The roof layer 360 may also be formed by a color filter. In this case, as illustrated in FIG. 9, color filters having different colors overlap with each other to form the partition wall portion 320. The partition wall portion 320 is positioned between the microcavities 305 adjacent to each other in a horizontal direction. The partition wall portion 320 is a portion that fills a separation space between the microcavities 305 adjacent to each other in a horizontal direction. The partition wall portion 320 may be formed in an extending direction of the data line 171 and may partition or define the microcavity 305. The roof layer 360 may also include an inorganic material.

An upper insulating layer 370 is positioned on the roof layer 360. The upper insulating layer 370 may be made of silicon nitride or silicon oxide.

A capping layer 390 is positioned on the upper insulating layer 370. The capping layer 390 is positioned even in the trench 307FP and covers the inlet 307 of the microcavity 305 exposed by the trench 307FP. The capping layer 390 includes an organic material or an inorganic material. In the drawing, it is illustrated that the liquid crystal material is removed from the trench 307FP, but the remaining liquid crystal material after being injected into the microcavity 305 may also exist in the trench 307FP. In this case, since the capping layer 390 contacts the liquid crystal material, the capping layer 390 may be made of a material, such as parylene, that does not react with the liquid crystal material.

A barrier layer 395 for preventing external moisture or oxygen from being permeated may be formed on the capping layer 390. The barrier layer 395 may be made of an inorganic material or an organic material, like the barrier layer 115 formed on the aforementioned flexible substrate 110.

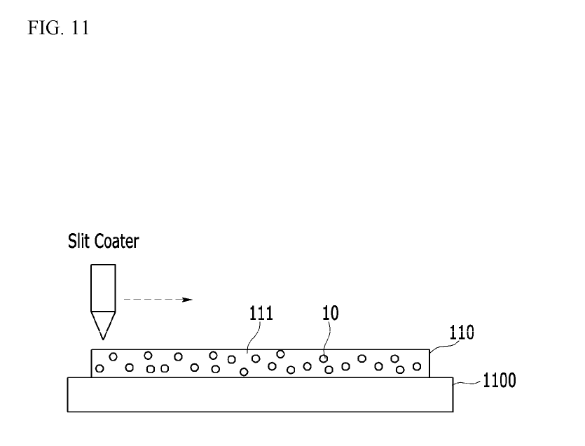

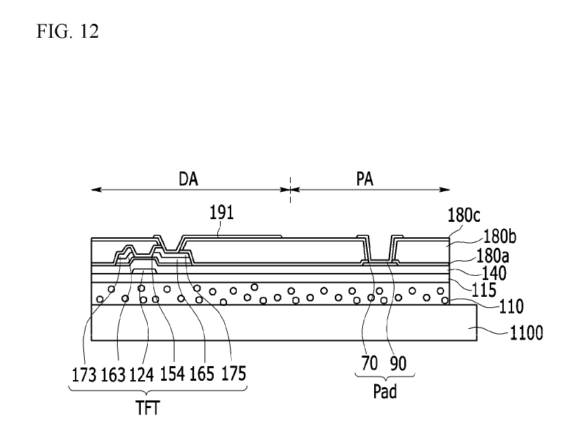

Hereinafter, a method of manufacturing a display device by using the flexible substrate described above is described with reference to FIGS. 11 to 19. A method to be described below may be modified by another method as an exemplary embodiment of the manufacturing method.

FIGS. 11 to 19 are process cross-sectional views illustrating a process of manufacturing a display device according to an exemplary embodiment of the present disclosure.

Since FIGS. 11 to 19 illustrate the display device based on the manufacturing process, constituent elements described in the aforementioned display device are simply illustrated or some constituent elements may be omitted, and the omitted constituent elements may be understood with reference to FIGS. 8 to 10. Further, a pixel formed in a display area DA where the image is displayed and a pad formed around the display area DA are exemplified.

Referring to FIG. 11, the flexible substrate 110 is formed on the carrier substrate 1100. The flexible substrate 110 may be formed by mixing particles with a plastic solution and then coating and curing the mixed particles on the carrier substrate 1100 by using a slit coater. Accordingly, the formed flexible substrate 110 may be in a state in which the particles 10 are distributed in the plastic layer 111. The flexible substrate 110 may have a thickness of a micrometer unit, for example, a thickness of several to tens of micrometers. According to an exemplary embodiment, the pre-formed flexible substrate 110 may be attached to the carrier substrate 1100.

While the flexible substrate 110 is attached to the carrier substrate 1100, the barrier layer 115 is formed on the flexible substrate 110, and elements and wires for transmitting or controlling various signals of the display device, the insulating layer, and the passivation layer are formed thereon.

In detail, to form the thin film transistor TFT, the gate electrode 124, the gate insulating layer 140, the semiconductor layer 154, the ohmic contacts 163 and 165, and the source and drain electrodes 173 and 175 are formed. When the gate electrode 124 is formed, a gate line (not illustrated) for transmitting the gate signal is formed, and when the source and drain electrodes 173 and 175 are formed, a data line (not illustrated) for transmitting the data signal is formed. The first passivation layer 180a, the second passivation layer 180b, and the third passivation layer 180c are formed on the source and drain electrodes 173 and 175, the data line, and the exposed portion of the semiconductor layer 154. Thereafter, the pixel electrode 191 is formed on the third passivation layer 180c, and the pixel electrode 191 is electrically and physically connected with the drain electrode 175 through a contact hole formed in the first, second and third passivation layers 180a, 180b, and 180c. When the source and drain electrodes 173 and 175 are formed, a first conductor 70 of the pad may be formed, when the pixel electrode 191 is formed, a second conductor 90 of the pad may be formed, and the second conductor 90 may be electrically and physically connected with the first conductor 70 through a contact hole formed in the first to third passivation layers 180a, 180b, and 180c.

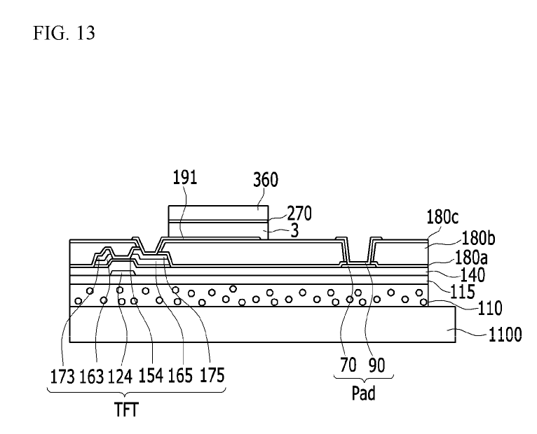

Referring to FIG. 13, the common electrode 270 and the roof layer 360 are formed on the pixel electrode 191, and the liquid crystal layer 3 is formed in the microcavity between the pixel electrode 191 and the common electrode 270. One microcavity may correspond to one pixel area or a plurality of pixel areas, and correspond to a part of one pixel area. The roof layer 360 may be made of a color filter or other organic materials, and may be made of an inorganic material.

When the process of forming the liquid crystal layer 3 is described in more detail, first, a sacrificial layer (not illustrated) is formed by coating and patterning an organic material such as a photoresist. A thickness of the sacrificial layer may be substantially the same as a thickness of the liquid crystal layer 3, that is, a cell gap. The sacrificial layer may be removed in a substantially parallel direction to the data line (not illustrated). The common electrode 270, the lower insulating layer (not illustrated), and the roof layer 360 are formed thereon. The roof layer 360 may be removed in a substantially parallel direction to the gate line (not illustrated) in a corresponding region between the adjacent pixel areas, and a partition wall which partitions adjacent microcavities in the region in which the sacrificial layer is removed may be formed. Thereafter, an upper insulating layer (not illustrated) is formed on the roof layer 360, and the sacrificial layer is exposed to the outside by partially removing the upper insulating layer 370, the lower insulating layer 350, and the common electrode 270. The sacrificial layer is removed by an oxygen (O₂) ashing process, a wet etching method, or the like to form the microcavity with an injection hole. Thereafter, an alignment layer (not illustrated) is formed by injecting an alignment material into the microcavity through the injection hole, and the liquid crystal layer 3 is formed by injecting the liquid crystal material.

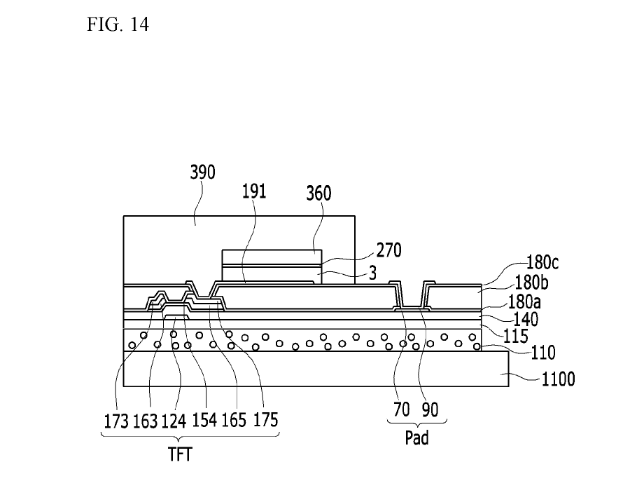

Referring to FIG. 14, the capping layer 390 covering the roof layer 360 and the injection hole of the microcavity is formed. A barrier layer (not illustrated) may be further formed on the capping layer 390.

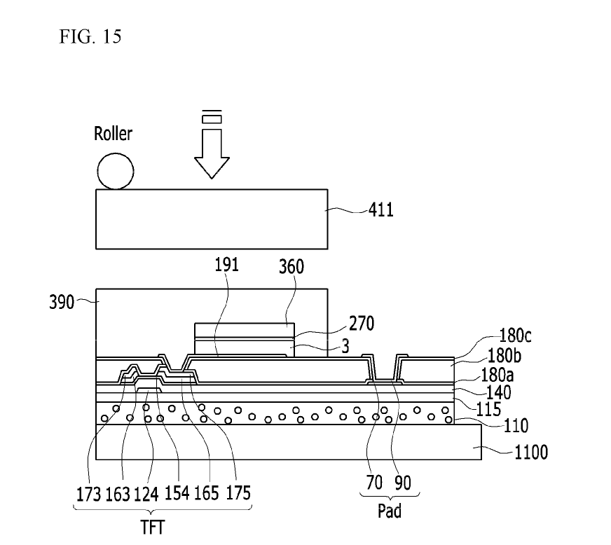

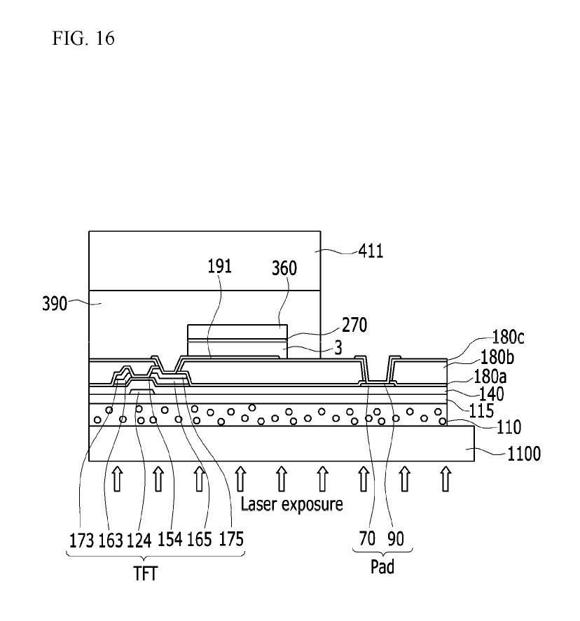

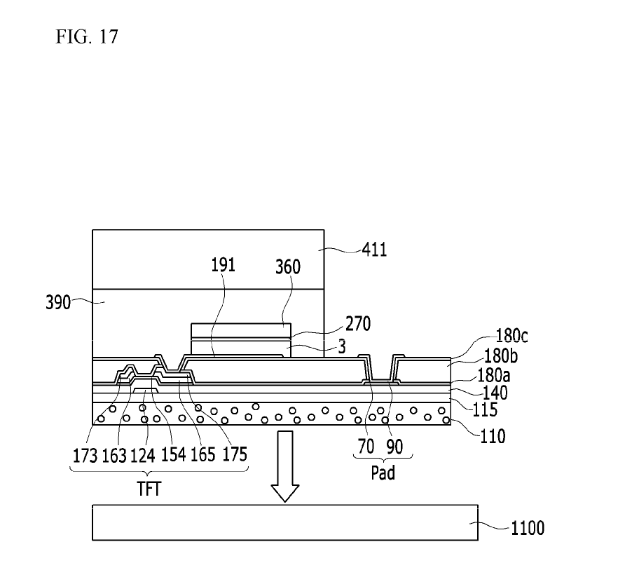

Referring to FIG. 15, an upper polarizer 411 is attached onto the capping layer 390 by using, for example, an adhesive and a roller. Thereafter, referring to FIGS. 16 and 17, a bonding between the carrier substrate 1100 and the flexible substrate 110 is broken or deteriorated by irradiating a laser to the carrier substrate 1100 side and then the carrier substrate 1100 is separated. Static electricity may be generated due to peeling electrification when the carrier substrate 1100 is separated, and may damage the elements of the display device. To prevent generation of the static electricity, the flexible substrate 110 may include an antistatic agent (not illustrated) that is dispersed in the plastic layer 111 or include a separate antistatic layer (not illustrated). As the antistatic agent, for example, a conductive polymer with a particulate shape, carbon black, metal, or the like may be included.

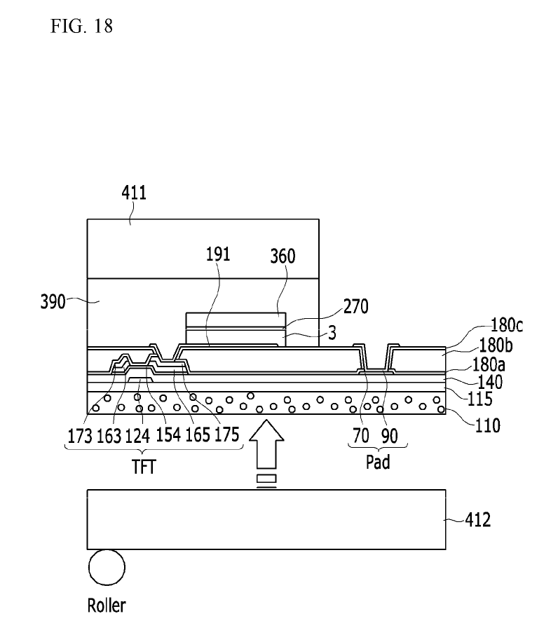

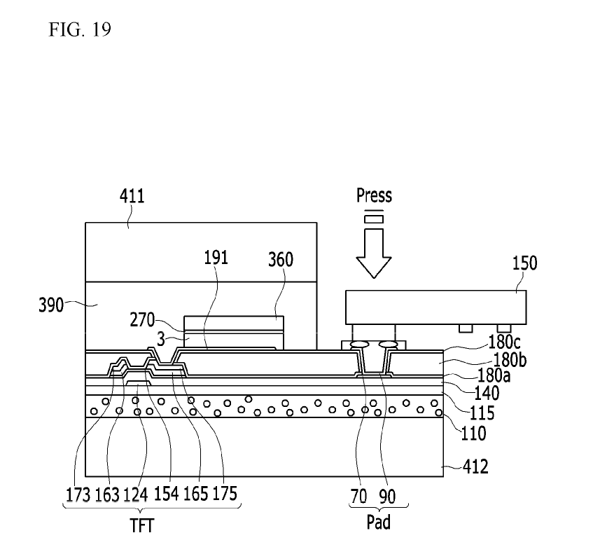

Referring to FIG. 18, a lower polarizer 412 is attached to a surface of the flexible substrate 110 in which the carrier substrate 1100 is removed by using an adhesive and a roller. Referring to FIG. 19, a flexible printed circuit board 150 is attached onto the second conductor 90 of the pad. A driving IC configured to generate a signal for controlling the display device may be mounted on the flexible printed circuit board 150 or a separate printed circuit board which is connected through the flexible printed circuit board 150, and directly mounted on the pad.

While the present system and method have been described in connection with exemplary embodiments, it is to be understood that the present system and method are not limited to the disclosed embodiments. On the contrary, the present system and method cover various modifications and equivalent arrangements included within the spirit and scope of the appended claims.

What is claimed is:

1. A flexible substrate for a display device, comprising:
a plastic layer; and
particles positioned in the plastic layer and reducing a thickness factor influencing warpage of the plastic layer.

2. The flexible substrate of claim 1, wherein:
each particle has a thickness of about 1 to about 10 μm.

3. The flexible substrate of claim 2, wherein:
the particles are made of the same material as the plastic layer.

4. The flexible substrate of claim 2, wherein:
the particles are each coated with a shell coating.

5. The flexible substrate of claim 4, wherein:
the shell coating is made of an inorganic material.

6. The flexible substrate of claim 1, wherein:
the particle includes a light-diffusing material.

7. The flexible substrate of claim 1, wherein:
the plastic layer includes a plurality of layers, and the particles are positioned only in a subset of layers of the plurality of layers.

8. The flexible substrate of claim 7, wherein:
a pattern is formed on an interface between the plurality of layers.

9. A display device, comprising:
a flexible substrate;
a thin film transistor positioned on the flexible substrate;
a pixel electrode positioned on the thin film transistor; and
an electro-optical active layer positioned on the pixel electrode,
wherein the flexible substrate includes
a plastic layer; and
particles positioned in the plastic layer and reducing a thickness factor influencing warpage of the plastic layer.

10. The display device of claim 9, wherein:
each particle has a thickness of about 1 to about 10 μm.

11. The display device of claim 10, wherein:
the particles are made of the same material as the plastic layer.

12. The display device of claim 10, wherein:
the particles are coated with a shell coating.

13. The display device of claim 12, wherein:
the shell coating is made of an inorganic material.

14. The display device of claim 9, wherein:
the particle includes a light-diffusing material.

15. The display device of claim 9, wherein:
the plastic layer includes a plurality of layers, and the particles are positioned only in a subset of layers of the plurality of layers.

16. The display device of claim 15, wherein:
a pattern is formed on an interface between the plurality of layers.

17. The display device of claim 9, wherein:
the electro-optical active layer is a liquid crystal layer positioned in a microcavity on the pixel electrode.

18. The display device of claim 17, further comprising:
a common electrode positioned on the liquid crystal layer; and
a roof layer positioned on the common electrode.

19. The display device of claim 9, wherein:
the electro-optical active layer is an organic emission layer.
